(19) United States
(12) Patent Application Publication
(10) Pub. No.: US 2008/0001678 A1
(43) Pub. Date: Jan. 3, 2008

(54) Voltage controlled oscillator and method of controlling frequency thereof

(76) Inventor: Takashi Otsuka, Kanagawa (JP)

Correspondence Address: MCDERMOTT WILL & EMERY LLP, 600 13TH STREET, NW, WASHINGTON, DC, 20005-3096, US

(21) Appl. No.: 11/802,630

(22) Filed: May 24, 2007

(30) Foreign Application Priority Data
May 25, 2006 (JP) 2006-145043

(51) Int. Cl. H03B 5/36; H03L 1/02

(52) U.S. Cl. 331/116 FE; 331/175

(57) ABSTRACT

A voltage controlled oscillator includes a first terminal and a second terminal between which a piezoelectric vibrator is to be connected, an amplifier which is connected between the first terminal and the second terminal, a first MOS transistor in which a drain thereof is connected to the first terminal, a second MOS transistor in which a drain thereof is connected to the second terminal, a first control signal generating circuit which supplies a first control signal to each gate of the first and second MOS transistors, and a second control signal generating circuit which supplies a second control signal to the drain of the second MOS transistor.

### BACKGROUND OF THE INVENTION

The present invention relates to a voltage controlled oscillator and a method of controlling the frequency thereof.

A temperature-compensated crystal oscillator which is used as a reference frequency source such as a mobile phone refers to a crystal oscillator having a property in which a variation in an oscillation frequency with a temperature is small, canceling a temperature property of a crystal oscillator (piezoelectric vibrator). The crystal oscillator is embodied by applying control voltage approximated to the temperature property of a cubic function of canceling the temperature property of the crystal oscillator to a control terminal of the voltage controlled oscillator. Recently, in a cellular phone and the like in which the global positioning system (GPS) is mounted, an oscillator in which the temperature compensation accuracy is in ±0.5 ppm are in great demand.

FIG. 1 shows the known voltage controlled oscillator. As an amplifier 1, an NPN transistor is used. A variable capacitance element uses a switching process of gate oxide film capacitances of MOS transistors 5 and 6. In addition, the variable capacitance element, as shown in FIG. 13, has a property in which a capacitance value varies in a straight direction according to the variation in a gate voltage by applying an oscillation signal with an amplitude to drain terminals of the MOS transistors 5 and 6 (for example, see Patent Document 1 for reference).

By applying a voltage to the variable capacitance element, it is possible to vary a load capacitance value within an oscillation loop to control the frequency. Besides the configuration shown in FIG. 1, it is possible to perform the same operation as long as the variable capacitance using the switching of the capacitance of the MOS transistor is used. For example, it is possible to the same operation as long as the configurations shown in FIGS. 4 to 6 are used.

Next, a property of a frequency f against control voltage VG of the voltage controlled oscillator shown in FIG. 1 will be described. FIG. 8 shows properties of a variable capacitance value C, a frequency f, and a sensitivity (df/dVG) against the control voltage VG. When the amplifier 1 is configured as the NPN transistor in FIG. 1, the upper limit of an XT terminal is determined as VBE (about 0.7 V) of the NPN transistor and the lower limit of an XTBAR terminal is determined as the saturation voltage (about 0.2 V) of the PNP transistor.

Consequently, since the operating voltage of the XT terminal is different from that of the XTBAR terminal as shown in FIG. 7, the MOS transistor 5 of the XT terminal and the MOS transistor 6 of the XTBAR terminal operate in the range of the respective different control voltage VG. By overlapping the f-VG property of the former with that of the latter, it is possible to obtain the broad control voltage range assuring a linearity of the total property, that is, a dynamic range of the control voltage. Since the sensitivity is fixed in the dynamic range, it is possible to control the oscillator using the voltage.

[Patent Document 1] JP-A-2003-318417

However, when an amplifier 1 is configured as an NPN transistor, the upper limit of an oscillation waveform of an XT terminal varies in accordance with a temperature with reference to FIG. 7. That is because a potential clamping (fixing) the oscillation amplitude of the XT terminal varies in accordance with a temperature due to a temperature property (−2 mV/° C.) of VBE of the NPN transistor.

In this case, as shown in FIG. 10, a control voltage range in which the f-VG property of an MOS transistor 5 of the XT terminal and that of an MOS transistor 6 of the XTBAR terminal are overlapped varies in accordance with a temperature. As a result, the inclination of the total f-VG property varies in accordance with a temperature, which means that the sensitivity of a frequency against the control voltage VG varies in accordance with a temperature.

At the time of applying the control voltage approximated to the cubic function to cancel the temperature property of the cubic function which a crystal oscillator has to a voltage controlled oscillator, the sensitivity of the voltage controlled oscillator varies in accordance with variation in a temperature. Consequently, the accuracy required to compensate the temperature property of the crystal oscillator may be degraded. The degradation of the temperature compensation accuracy results from an overcompensation for the temperature property of crystal because the f-VG sensitivity increases at a low temperature and results from the insufficient the compensation for the temperature property of crystal because the f-VG sensitivity decreases at a high temperature. In addition, the temperature property of an automatic frequency control (AFC) for controlling the frequency of an oscillator is degraded due to the variation in the temperature property of the sensitivity.

### SUMMARY OF THE INVENTION

In order to solve the above mentioned problem, the invention has been made to provide a voltage controlled oscillator in which the sensitivity (sensitivity of the f-VG property) of the frequency f against the control voltage VG does not vary in accordance with a temperature and a method of controlling the frequency thereof.

According to an aspect of the invention, there is provided a voltage controlled oscillator comprising:

a first terminal and a second terminal between which a piezoelectric vibrator is to be connected;

an amplifier which is connected between the first terminal and the second terminal;

a first MOS transistor in which a drain thereof is connected to the first terminal;

a second MOS transistor in which a drain thereof is connected to the second terminal;

a first control signal generating circuit which supplies a first control signal to each gate of the first and second MOS transistors; and

a second control signal generating circuit which supplies a second control signal to the drain of the second MOS transistor.

In the above mentioned configuration, by allowing the second signal in the first terminal to have the temperature property to cancel the temperature property of the amplitude upper limit, the range of the control voltage VG in which the f-VG property of the first MOS transistor is overlapped with that of the second MOS transistor may remain fixed even when a temperature varies. Consequently, it is possible to cancel the sensitivity temperature property of the f-VG property of the total property.

In addition, the voltage controlled oscillator includes a piezoelectric vibrator which is connected between the first terminal and the second terminal.

In the above mentioned configuration, by allowing the second signal in the input end of an amplifier to have the temperature property to cancel the temperature property of the amplitude upper limit, the range of the control voltage VG in which the f-VG property of the first MOS transistor is overlapped with that of the second MOS transistor may remain fixed even when a temperature varies. Consequently, it is possible to cancel the sensitivity temperature property of the f-VG property of the total property.

In the voltage controlled oscillator, the first control signal includes at least one of a temperature compensation control signal, an external voltage frequency control signal, and a variation compensation control signal.

In the voltage controlled oscillator, the second control signal is a voltage signal to cancel a temperature property of an oscillator sensitivity.

According to another aspect of the invention, there is provided a voltage controlled oscillator, comprising:

a first terminal and a second terminal between which a piezoelectric vibrator is to be connected;

an amplifier which is connected between the first terminal and the second terminal;

a first MOS transistor and a second MOS transistor in which drains thereof are connected to the first terminal;

a third MOS transistor and a fourth MOS transistor in which drains thereof are connected to the second terminal;

a first control signal generating circuit which supplies a first control signal to each gate of the first and third MOS transistors;

a second control signal generating circuit which supplies a second control signal to each gate of the second and fourth MOS transistors; and

a third control signal generating circuit which supplies a third control signal to the drains of the third and fourth MOS transistors.

In the above mentioned configuration, by allowing the third signal in the first terminal to have the temperature property to cancel the temperature property of the amplitude upper limit, the range of the control voltage VG in which the f-VG properties of the first and second MOS transistors are overlapped with those of the third and fourth MOS transistors may remain fixed even when a temperature varies. Consequently, it is possible to cancel the sensitivity temperature property of the f-VG property of the total property.

In addition, the voltage controlled oscillator may include a piezoelectric vibrator.

In the above mentioned configuration, by allowing the third signal in the input end of an amplifier to have the temperature property to cancel the temperature property of the amplitude upper limit, the range of the control voltage VG in which the f-VG properties of the first and second MOS transistors are overlapped with those of the third and fourth MOS transistors may remain fixed even when a temperature varies. Consequently, it is possible to cancel the sensitivity temperature property of the f-VG property of the total property.

In the voltage controlled oscillator, the first control signal may include at least one of a temperature compensation control signal, an external voltage frequency control signal, and a variation compensation control signal.

In the voltage controlled oscillator, the second control signal may include at least one of a temperature compensation control signal, an external voltage frequency control signal, and a variation compensation control signal.

In the voltage controlled oscillator, the third control signal may be a voltage signal to cancel a temperature property of an oscillator sensitivity.

According to still another aspect of the invention a method of controlling the frequency of a voltage controlled oscillator which has a plurality of control terminals, the method of supplying a first control signal for controlling an oscillation frequency to a first control terminal; and supplying a second control signal for canceling the temperature property of an oscillator sensitivity to a second control terminal.

In a voltage controlled oscillator according to the invention, by allowing a second and fifth signals to have the temperature property to cancel the temperature property of the amplitude upper limit, the range of the control voltage VG in which the f-VG properties of a first MOS transistor is overlapped with that of a second MOS transistor may remain fixed even when a temperature varies. Consequently, it is possible to cancel the sensitivity temperature property of the f-VG property of the total property.

In addition, the sensitivity does not vary in accordance with a temperature. Consequently, it is possible to improve the temperature compensation accuracy when the control voltage approximated to a cubic function is applied to the voltage controlled oscillator in order to cancel the temperature property of the cubic function which a crystal oscillator has. Moreover, it is possible to improve the temperature property of an AFC property.

### BRIEF DESCRIPTION OF THE DRAWINGS

The above objects and advantages of the present invention Will become more apparent by describing in detail preferred exemplary embodiments thereof with reference to the accompanying drawings, wherein:

FIG. 1 is a diagram illustrating an overview circuit configuration of the known voltage controlled oscillator;

FIG. 2 is a diagram illustrating the overview circuit configuration of a voltage controlled oscillator according to a first embodiment of the invention;

FIG. 3 is a diagram illustrating an overview circuit configuration of the voltage controlled oscillator according to a second embodiment of the invention;

FIG. 4 is a diagram illustrating a first exemplary circuit configuration of a variable capacitance of the voltage controlled oscillator;

FIG. 5 is a diagram illustrating a second exemplary circuit configuration of the variable capacitance of the voltage controlled oscillator;

FIG. 6 is a diagram illustrating a third exemplary circuit configuration of the variable capacitance of the voltage controlled oscillator;

FIG. 7 is a diagram illustrating an oscillation waveform of the known circuit;

FIG. 8 is diagrams illustrating C-V property, f-V property, and the sensitivity properties of the voltage controlled oscillator;

FIG. 9 is a diagram illustrating the oscillation waveforms according to the first and the second embodiments;

FIG. 10 is diagrams illustrating the f-V property and the sensitivity property of the known circuit;

FIG. 11 is diagrams illustrating the f-V property and the sensitivity property according to the first and the second embodiments;

FIG. 12 is a block diagram illustrating a control signal generating circuit according to the first and the second embodiments; and

FIG. 13 is a diagram illustrating the operation of a variable capacitance element.

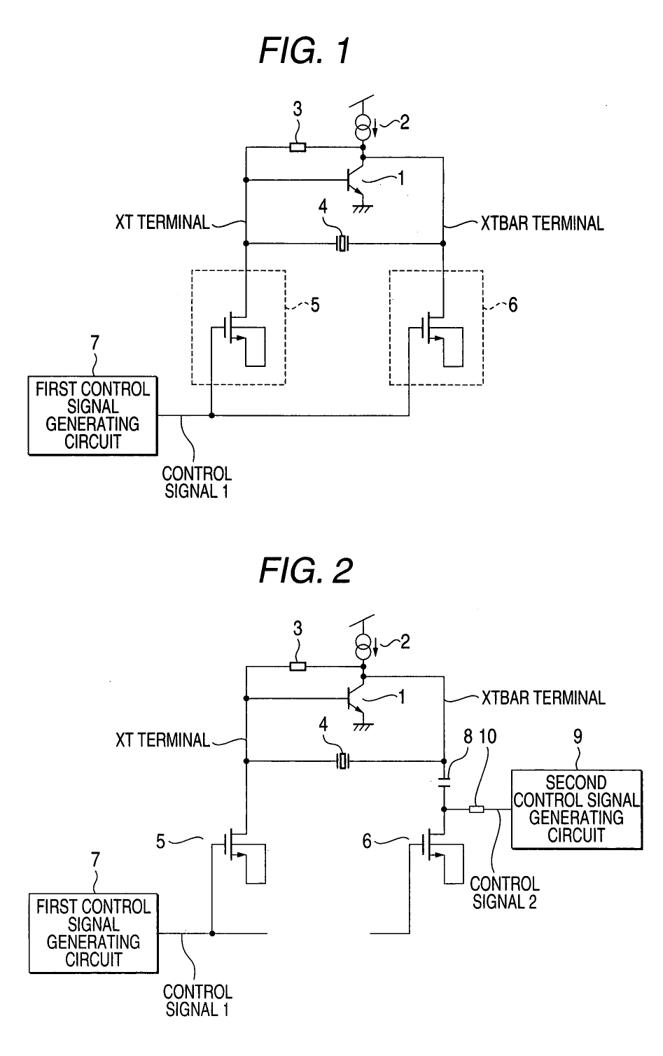

### DETAILED DESCRIPTION OF THE PREFERRED EMBODIMENTS

Hereinafter, embodiments of the invention will be described with reference to drawings.

### First Embodiment

FIG. 2 shows an overall configuration of a voltage controlled oscillator according to a first embodiment of the invention. As shown in FIG. 2, the voltage controlled oscillator has a piezoelectric vibrator 4, an XT terminal and an XTBA terminal to which the piezoelectric vibrator 4 is connected, an amplifier 1 connected in parallel to the piezoelectric vibrator 4, a load capacitance, as a load capacitance connected in parallel to the piezoelectric vibrator 4, in which first and second MOS transistors 5 and 6 are connected in series, a first control signal generating circuit 7 supplying a first control signal to each gate terminal (control terminal 1) of the first and the second MOS transistors 5 and 6, a DC cut capacitance 8 disposed between the XTBAR terminal and the drain terminal of the second MOS transistor 6, and a second control signal generating circuit 9 supplying a second control signal to a control terminal 2 connected the drain terminal of the second MOS transistor 6 via a high frequency removing resistor 10.

In this case, the first control signal supplied from the first control signal generating circuit 7 includes at least one of a temperature compensation control signal, an external voltage frequency control signal, and a variation compensation control signal. The second control signal supplied from the second control signal generating circuit 9 serves as a voltage signal for canceling the temperature property of the oscillator sensitivity.

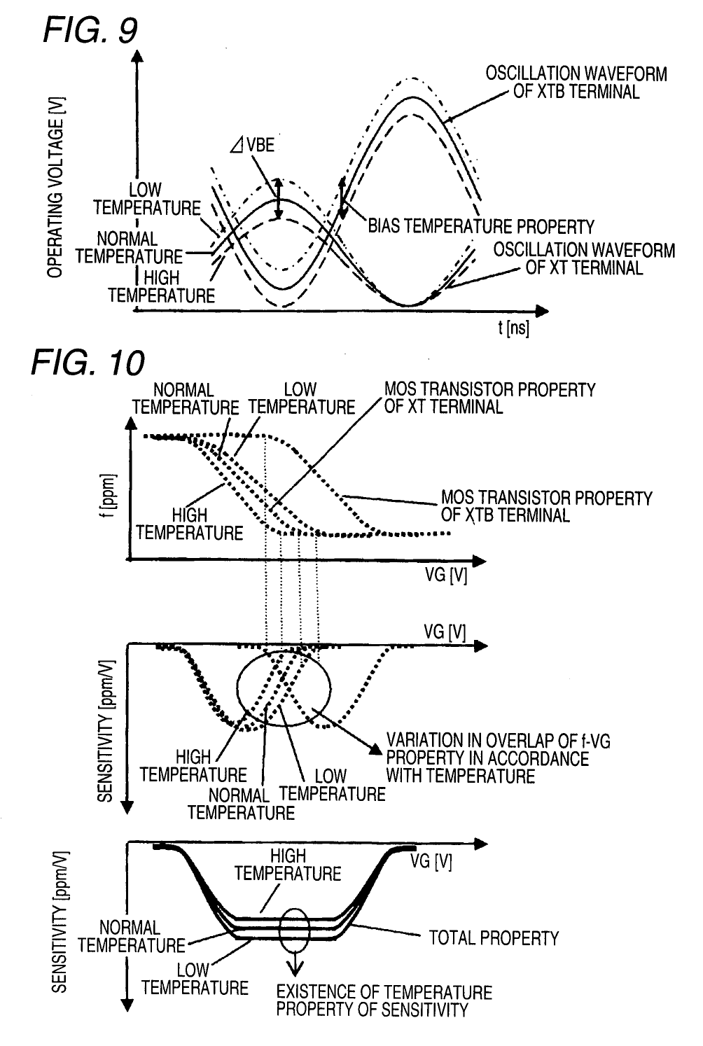

As shown in FIG. 9, an upper limit of the amplitude of the XT terminal varies in accordance with a temperature because of the VBE temperature property (−2 mV/° C.) of the NPN transistor 1 constituting an oscillation circuit (about Δ0.26 V in the range of −40° C. to 90° C.). In order to have the temperature property to cancel a lower limit of the amplitude of the drain terminal of the second MOS transistor 6, the second control signal generating circuit 9 connected to the control terminal 2 applies the voltage having the temperature property of −2 mV/° C., for example, to the lower limit of the amplitude. In this manner, the bias of the drain terminal of the MOS transistor 6 has the temperature property of −2 mV/° C. The circuit according to the first embodiment is required to have the temperature property of about −4 mV/° C. in order to cancel the temperature property (about −2 mV/° C.) of the threshold level of the MOS transistors 5 and 6 used as a variable capacitance as well.

According to the first embodiment, by allowing a voltage applied to the control terminal 2 to have the temperature property to cancel the temperature property of the amplitude upper limit of the XT terminal, the range of the control voltage VG in which the f-VG property of the first MOS transistor 5 is overlapped with that of the second MOS transistor 6 remains fixed even when a temperature varies. Consequently, it is possible to cancel the sensitivity temperature property of the f-VG property of the total property.

Next, a configuration of the second control signal generating circuit will be described. Since a temperature sensor is generally built in the temperature compensation oscillator, the temperature compensation oscillator can generate the compensation voltage of a cubic function from the output voltage of the temperature sensor. According to the embodiment, it is possible to allow the bias of the drain terminal of the MOS transistor 6 to have the temperature property, as shown in FIG. 12, by applying the output voltage having a negative temperature property of the temperature sensor constituted by a current source 30 and a diode 31 to the control terminal 2 of the voltage controlled oscillator via an amplifier 32. According to the embodiment, it is possible to embody the invention without supplementing a new temperature sensor circuit.

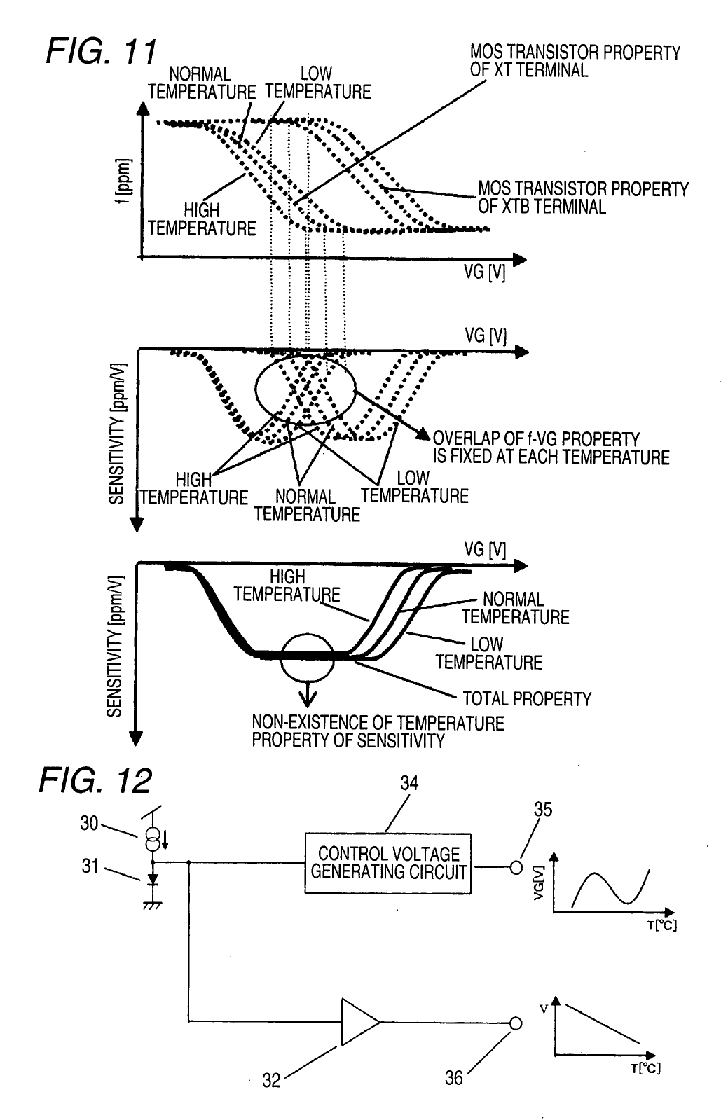

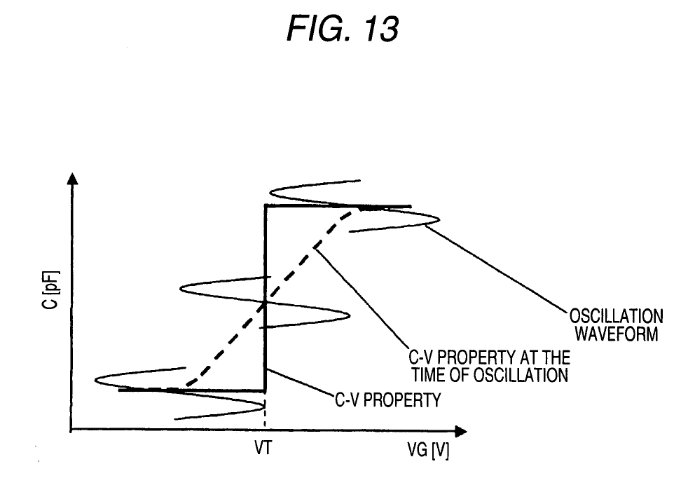

In the configuration according to the embodiment, by allowing the second control signal to have the temperature property, as shown in FIG. 11, the range of the control voltage in which the f-Vg property of the first MOS transistor 5 is overlapped with that of the second MOS transistor 6 can remain fixed even when a temperature varies. Consequently, it is possible to cancel the temperature property of the sensitivity of the frequency f against the control voltage VG of the total property.

In addition, the sensitivity does not vary in accordance with a temperature. Consequently, it is possible to improve the temperature compensation accuracy when the control voltage approximated to the cubic function is applied to the voltage controlled oscillator in order to cancel the temperature property of the cubic function which the crystal oscillator 4 has. Moreover, it is possible to improve the temperature property of the AFC property.

### Second Embodiment

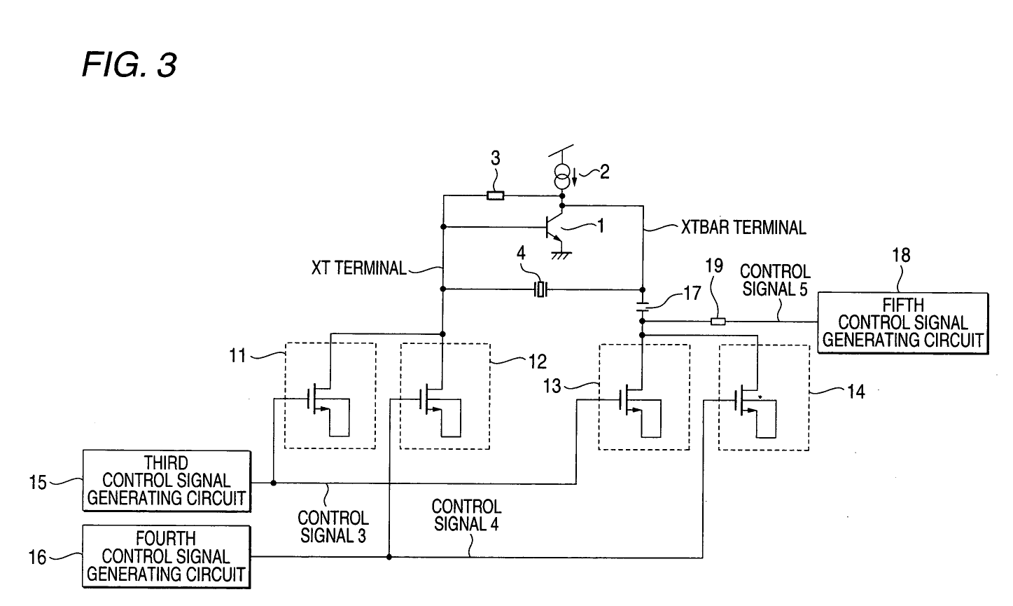

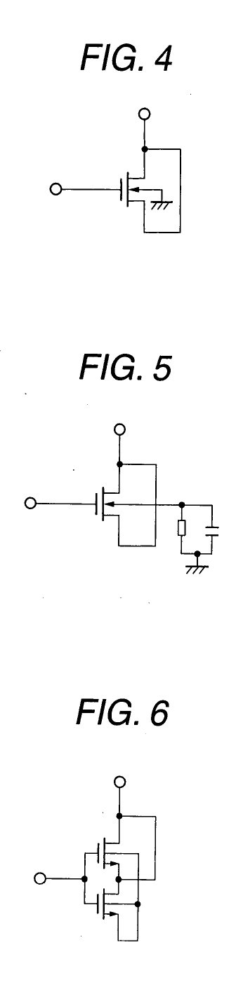

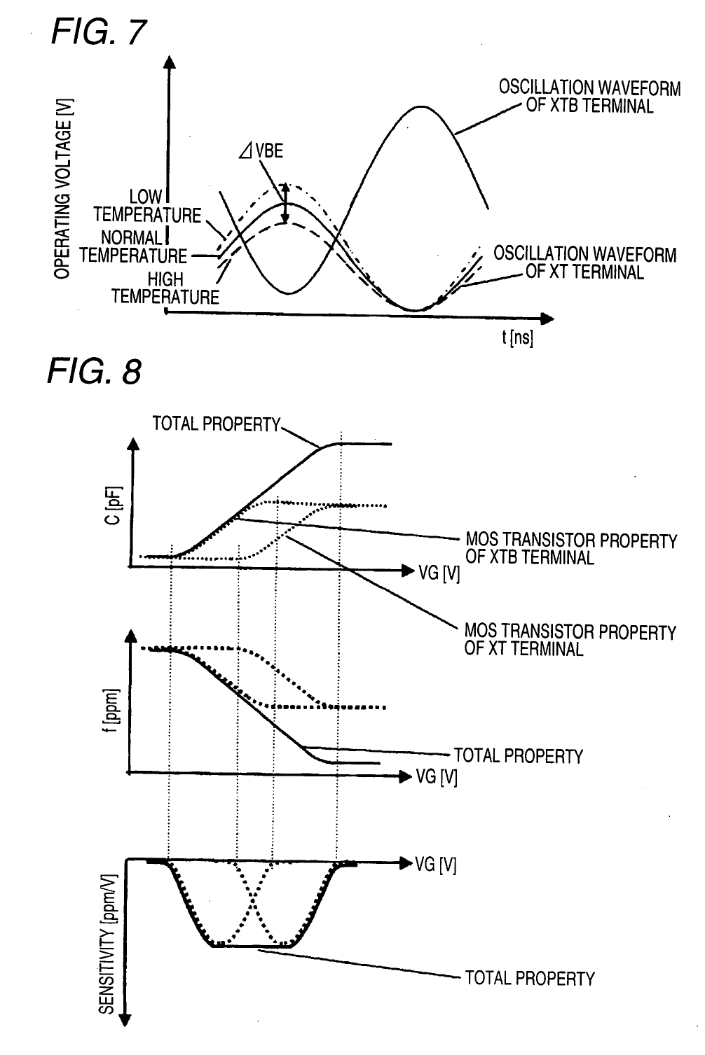

FIG. 3 is a diagram illustrating an overview configuration of a voltage controlled oscillator according to a second embodiment of the invention. As shown in FIG. 3, the voltage controlled oscillator has a piezoelectric vibrator 4; an XT terminal and an XTBAR terminal to which the piezoelectric vibrator 4 is connected; an amplifier 1 connected in parallel to the piezoelectric vibrator 4; a load capacitance which is configured as a load capacitance connected in parallel to the piezoelectric vibrator 4 and to which first and third MOS transistors 11 and 13 are connected in series; a load capacitance to which second and fourth MOS transistors 12 and 14 are connected in series; a third control signal generating circuit 15 supplying a third control signal to each gate terminal (control terminal 3) of the first and the third MOS transistors 11 and 13; a fourth control signal generating circuit 16 supplying a fourth control signal to each gate terminal (control terminal 4) of the second and the fourth MOS transistors 12 and 14; a DC cut capacitance 17 disposed between the XTBAR terminal and the drain terminal of the third and the fourth MOS transistors 13 and 14; and a fifth control signal generating circuit 18 supplying a fifth control signal to a control terminal 5 connected to the third and the fourth MOS transistors 13 and 14 via a high frequency removing resistor 19.

In this case, the third control signal supplied from the third control signal generating circuit 15 and the fourth control signal supplied from the fourth generator 16 have at least any one of a temperature compensation control signal, an external voltage frequency control signal, and a variation compensation control signal. The fifth control signal supplied from the fifth control signal generating circuit 18 is a voltage signal to cancel the temperature property of the oscillator sensitivity.

Similarly with the first embodiment, a circuit for generating the voltage having a temperature property as the fifth control signal is configured. In order to have the temperature property to cancel the lower limit of the amplitude of the drain terminal of the second MOS transistor 12, the fifth control signal generating circuit 18 applies the voltage having the temperature property of −2 mV/° C., for example, to the lower limit of the amplitude. In this manner, the bias of the drain terminal of the MOS transistor 6 has the temperature property of −2 mV/° C.

According to the embodiment, the voltage applied to the control terminal 5 has the temperature property, for example, to cancel the temperature property of the amplitude upper limit of the XT terminal, such that the range of control voltage VG in which an f-VG property of the first and the second MOS transistors 11 and 12 is overlapped with that of the second and the fourth MOS transistors 13 and 14 remains fixed at the time of variation in a temperature. Consequently, it is possible to cancel the sensitivity temperature property of the f-VG property of the total property.

In the configuration of the fifth control signal generating circuit 18, the bias of the drain terminal of the MOS transistor 6 can have the temperature property as well by applying the output voltage having the negative temperature property of a built-in temperature sensor to the control terminal 5 of the voltage controlled oscillator via the amplifier 32 similarly with the second control signal generating circuit 9. In addition, when the amplifier of the voltage controlled oscillator is configured as a PNP, NMOS, or PMOS transistor, the method is the same and it is possible to cancel the variation in amplitude in accordance with a temperature.

According to the embodiment, by allowing the fifth control signal to have the temperature property, the range of the control voltage VG in which the f-VG property of the first and the second MOS transistors 11 and 12 is overlapped with that of the third and the fourth MOS transistors 13 and 14 can remain fixed, even when a temperature varies as shown in FIG. 11. Consequently, it is possible to cancel the temperature property of the sensitivity of the frequency f against the control voltage VG of the total property.

In addition, sine the sensitivity does not vary in accordance with a temperature, it is possible to improve a temperature compensation accuracy as well when the control voltage approximated to the cubic function is applied to the voltage controlled oscillator in order to cancel the temperature property of the cubic function which the crystal oscillator 4 has. Furthermore, it is possible to improve the temperature property of the AFC property.

The invention has an advantage of the fact that a sensitivity of a frequency f against a control voltage VG (sensitivity of f-VG property) does not vary in accordance with a temperature and can be used as a method of controlling a voltage controlled oscillator and the frequency thereof.

Although the invention has been illustrated and described for the particular preferred embodiments, it is apparent to a person skilled in the art that various changes and modifications can be made on the basis of the teachings of the invention. It is apparent that such changes and modifications are within the spirit, scope, and intention of the invention as defined by the appended claims.

The present application is based on Japan Patent Application No. 2006-145043 filed on May 25, 2006, the contents of which are incorporated herein for reference.

What is claimed is:

1. A voltage controlled oscillator comprising:
a first terminal and a second terminal between which a piezoelectric vibrator is to be connected;
an amplifier which is connected between the first terminal and the second terminal;
a first MOS transistor in which a drain thereof is connected to the first terminal;
a second MOS transistor in which a drain thereof is connected to the second terminal;
a first control signal generating circuit which supplies a first control signal to each gate of the first and second MOS transistors; and
a second control signal generating circuit which supplies a second control signal to the drain of the second MOS transistor.

2. The voltage controlled oscillator according to claim 1, further comprising:
a piezoelectric vibrator which is connected between the first terminal and the second terminal.

3. The voltage controlled oscillator according to claim 1, wherein the first control signal includes at least one of a temperature compensation control signal, an external voltage frequency control signal, and a variation compensation control signal.

4. The voltage controlled oscillator according to claim 1, wherein the second control signal is a voltage signal to cancel a temperature property of an oscillator sensitivity.

5. A voltage controlled oscillator, comprising:
a first terminal and a second terminal between which a piezoelectric vibrator is to be connected;
an amplifier which is connected between the first terminal and the second terminal;
a first MOS transistor and a second MOS transistor in which drains thereof are connected to the first terminal;
a third MOS transistor and a fourth MOS transistor in which drains thereof are connected to the second terminal;
a first control signal generating circuit which supplies a first control signal to each gate of the first and third MOS transistors;
a second control signal generating circuit which supplies a second control signal to each gate of the second and fourth MOS transistors; and
a third control signal generating circuit which supplies a third control signal to the drains of the third and fourth MOS transistors.

6. The voltage controlled oscillator according to claim 5, further comprising a piezoelectric vibrator which is connected between the first terminal and the second terminal.

7. The voltage controlled oscillator according to claim 5, wherein the first control signal includes at least one of a temperature compensation control signal, an external voltage frequency control signal, and a variation compensation control signal.

8. The voltage controlled oscillator according to claim 5, wherein the second control signal includes at least one of a temperature compensation control signal, an external voltage frequency control signal, and a variation compensation control signal.

9. The voltage controlled oscillator according to claim 5, wherein the third control signal is a voltage signal to cancel a temperature property of an oscillator sensitivity.

10. A method of controlling the frequency of a voltage controlled oscillator having a plurality of control terminals, the method comprising:
supplying a first control signal for controlling an oscillation frequency to a first control terminal; and
supplying a second control signal for canceling the temperature property of an oscillator sensitivity to a second control terminal.
